(19) United States
(12) Patent Application Publication
(10) Pub. No.: US 2025/0273466 A1
(43) Pub. Date: Aug. 28, 2025

(54) VERTICAL FEATURE GROWTH USING FLUORINE-CONTAINING GAS

(71) Applicant: Tokyo Electron Limited, Tokyo (JP)

(72) Inventors: Indroneil Roy, Albany, NY (US); Jason Marion, Albany, NY (US); Yusuke Lent-Yoshida, Albany, NY (US); Yun Han, Albany, NY (US)

(21) Appl. No.: 18/588,751

(22) Filed: Feb. 27, 2024

(51) Int. Cl. H01L 21/033; H01J 37/32; H01L 21/308; H01L 21/311

(52) U.S. Cl. CPC H01L 21/0337; H01J 37/32449; H01L 21/308; H01L 21/31144; H01J 2237/334

(57) ABSTRACT

A method of vertically growing a material, such as an oxide, on features using a fluorine-containing gas includes performing the following concurrent steps: depositing the material on a relief pattern, such as a mask layer, using a precursor gas and a reactant gas, such as an oxygen-containing gas, and etching side protrusions of the material vertically overlapping recesses using the fluorine-containing gas. The relief pattern includes the features separated by the recesses, which may expose an underlying layer. The method may be performed in situ in an etching chamber of a plasma etching system, such as using a controller operatively coupled to at least one gas source configured to supply the precursor gas, the reactant gas, and the fluorine-containing gas into the etching chamber.

### TECHNICAL FIELD

The present invention relates generally to vertical feature growth of an existing relief pattern, and, in particular embodiments, to systems and methods for vertically growing features using a fluorine-containing gas.

### BACKGROUND

Microelectronic device fabrication typically involves a series of manufacturing techniques that include formation, patterning, and removal of a number of layers of material on a substrate. Etch masks may be formed (e.g., deposited, grown, patterned) to protect regions of the substrate and allow for pattern transfer via etching. Wet or dry etching processes may be used, with plasma etching processes being an example of a dry etching process. Etching processes are used extensively to form a network of electronic components and interconnect elements (e.g., transistors, resistors, capacitors, metal lines, contacts, and vias) integrated in a monolithic structure (i.e., an integrated circuit).

Various processes can be used to form relief patterns (e.g., photolithographic processes to form etch masks by exposing a photoresist layer to structured actinic radiation and developing the photoresist). The relief patterns have a non-planar topography. That is, the relief pattern is made up of features separated by recesses that are formed in a material layer (or layers). In some cases, the height of the features is shorter than desired, whether initially upon formation of the relief pattern or subsequent to formation (e.g., because of mask loss during an etching process). Inadequate feature height may result in undesirable effects, such as non-uniform etch profile or inaccurate pattern transfer to an underlying layer during an etching process.

Material can be deposited on relief patterns after their formation using various deposition processes, including physical vapor deposition (PVD), chemical vapor deposition (CVD), atomic layer deposition (ALD), molecular layer deposition (MLD), and others. Additionally, many deposition processes may incorporate plasma, such as plasma-enhanced CVD (PE-CVD), plasma-enhanced ALD (PE-ALD), etc. Some deposition processes are generally unsuitable for increasing feature height (such as PVD processes which can damage the structures). Many deposition processes also require specific deposition equipment that is different from other equipment that makes use of the relief pattern.

For example, in the case of etching an underlying layer using the relief pattern as an etch mask, the etching equipment may be different than the deposition equipment. This may be undesirable because since a substrate with the relief pattern must be removed from one tool and moved to another tool to deposit material on the relief pattern. In the case of mask loss during an etching process, the substrate must be removed from the etch tool, moved to a deposition tool to deposit a material, and then moved back to the etch tool to continue etching. This results in a decrease in throughput and potentially introduces opportunities for contamination.

Typical deposition processes also do not result in deposited structures that are true to the relief pattern. For example, ALD and MLD (and sometimes CVD processes to some extent) are conformal deposition processes and result in material being deposited on sidewalls of the features of the relief pattern and/or on bottom surfaces of the recesses. CVD processes deposit material isotropically (i.e., material grows at a substantially equal rate in all directions). Conformal and isotropic deposition processes deposit material in the openings of the recesses between features (whether through conformal deposition that increases the sidewall thickness or through isotropic deposition that grows material laterally into and over the openings). This narrows and eventually clogs the openings of the relief pattern so that it can no longer be used for its intended purpose (e.g., as an etch mask or providing access to interior regions of a material).

Therefore, improved systems and methods for feature growth that increases feature height without the drawbacks associated with conventional deposition techniques such as clogging and reduced throughput, may be desirable.

### SUMMARY

In accordance with an embodiment of the invention, a method includes performing the following concurrent steps: depositing a material on a relief pattern using a precursor gas and a reactant gas, and etching side protrusions of the material vertically overlapping recesses using a fluorine-containing gas. The relief pattern includes features separated by the recesses.

In accordance with another embodiment of the invention, a method includes vertically growing oxide on features of a mask layer. The features are separated by openings exposing an underlying layer. Vertically growing the oxide includes concurrently depositing the oxide on the features using a precursor gas and an oxygen-containing gas. The method further includes etching side protrusions of the oxide vertically overlapping the openings using a fluorine-containing gas, and etching the underlying layer through the openings using the oxide as an etch mask.

In accordance with still another embodiment of the invention, a plasma etching system includes an etching chamber and a substrate support disposed in the etching chamber. The substrate support is configured to support a substrate including a mask layer disposed over an underlying layer. The mask layer includes a relief pattern that includes features separated by openings exposing the underlying layer. The plasma etching system further includes at least one gas source fluidically coupled to the etching chamber and configured to supply a precursor gas, an oxygen-containing gas, and a fluorine-containing gas into the etching chamber, and a controller operatively coupled to the at least one gas source. The controller includes a processor and a non-transitory computer-readable medium storing a program including instructions that, when executed by the processor, perform a method in situ in the etching chamber. The method includes vertically growing oxide on the features of the mask layer and etching the underlying layer through the openings using the oxide as an etch mask. Vertically growing the oxide includes concurrently depositing the oxide on the features using the precursor gas and the oxygen-containing gas, and etching side protrusions of the oxide vertically overlapping the openings using the fluorine-containing gas.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates an example process for growing features of a relief pattern by concurrently depositing oxide and etching side protrusions of the oxide in accordance with embodiments of the invention;

FIGS. 2A-2C illustrate another example process for growing features of a relief pattern by concurrently depositing oxide and etching side protrusions of the oxide, where the features are separated by openings as part of a mask layer and an underlying layer is etched through the openings using the oxide as an etch mask in accordance with embodiments of the invention;

FIG. 3 illustrates an example relief pattern conceptually demonstrating etching of side protrusions of a deposited material resulting in vertical feature growth in accordance with embodiments of the invention;

FIG. 4 illustrates a qualitative graph of relative vertical growth versus lateral relative growth demonstrating the operating regime for feature growth in accordance with embodiments of the invention;

FIG. 5 illustrates an example plasma processing system that includes an etching chamber and a controller configured to both grow features of a relief pattern by concurrently depositing a material and etching side protrusions of the material and also to etch an underlying layer using the material as an etch mask in situ in the etching chamber in accordance with embodiments of the invention; and

FIG. 6 illustrates an example method of growing features of a relief pattern in accordance with embodiments of the invention.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope. Unless specified otherwise, the expressions “around”, “approximately”, and “substantially” signify within 10%, and preferably within 5% of the given value or, such as in the case of substantially zero, less than 10% and preferably less than 5% of a comparable quantity.

It is often desirable to vertically grow material on upper surfaces of a relief pattern (e.g., an etch mask) when the height of features of the relief pattern is too low or becomes too low (such as during an etching process). In the specific application of etching, the goal is to grow the mask so that the etching process can continue etching a target material (whereas it may be unable to continue otherwise due to lack of selectivity once the mask material is too low or entirely gone) . . . . For example, if a material can be deposited vertically at upper surfaces of the features without substantially depositing material in or over openings, the material of the etch mask that has been lost during the etching process (or even that never existed due to the process used to form the mask, such as for thin mask materials like metal-oxide resist (MOR) materials) can be “regrown” allowing the etching of the target material to continue.

Conventional feature growth techniques use deposition methods that are subject to clogging of the features themselves. This is problematic because clogging of the features of the relief pattern will often render the relief pattern ineffective for its intended purpose (such as functioning as an etch mask for etching of an underlying target material). For this reason, any deposition process that is used for feature growth must be optimized to avoid clogging (which is often not possible with conventional techniques).

Additionally, even when clogging using conventional feature growth techniques can be avoided, substantial narrowing the openings between feature often still occurs. That is, conventional deposition techniques are characterized by uncontrolled growth; there's no preferential directionality to the deposition process and there is substantially isotropic deposition in the regions where the material is deposited (e.g., lateral growth occurs at a substantially similar rate as vertical growth). For example, oxide that is deposited using conventional methods may grow vertically but also grows laterally, which overhangs openings between features and can decrease the ability of etchants to reach deep into recesses in subsequent etching steps.

Therefore, feature growth that is as close to the profile of the relief pattern as possible is desirable (e.g., so that subsequent etching of the underlying film can continue with the etch profile substantially unaffected). Even small side protrusions of a deposited material can narrow openings which may be detrimental to continuing to etch an underlying film and achieve desired profile characteristics.

In accordance with various embodiments herein described, the invention proposes vertical feature growth methods that simultaneously deposit a material on features of a relief pattern while etching side protrusions of the deposited material using a fluorine-containing gas. Specifically, in various embodiments, a method of vertically growing a deposited material on features of a relief pattern includes concurrent deposition of the material on the relief pattern and etching of side protrusions of the material (i.e., material vertically overlaps, or overhangs, the recesses). The material (e.g., an oxide, nitride, etc.) is deposited using a precursor gas (such as a precursor including silicon, aluminum, boron, or others) and a reactant gas (e.g., containing oxygen, nitrogen, etc.) while the side protrusions are etched using a fluorine-containing gas (such as a fluorocarbon compound, fluoronitrogen compound, and the like). That is, the vertical feature growth methods use a mixture of gases including the precursor gas, the reactant gas, and the fluorine-containing gas.

The relief pattern may include a mask layer and the material grown on the features may be used as an etch mask in a subsequent etching step. In some embodiments, bias power is also applied to a substrate that includes the relief pattern during the vertical feature growth. Source power may also be applied during the feature growth step (e.g., to generate plasma from the mixture of gases). Of course, source power and/or bias power may also be applied (with the same or different parameters) during the subsequent etching step, such as when using a plasma etching process, for example. In various embodiments, the feature growth step and an etching step are alternated as part of a cycle. Both the feature growth step and any subsequent etching may be performed in situ in the same chamber (e.g., in situ in an etching chamber, such as a plasma etching chamber). That is, in some embodiments, an etching system can be operated in an etch mode when using the grown material as an etch mask and in feature growth mode (i.e., a deposition mode) when vertically growing additional material on features of the mask layer.

One type of conventional deposition method seeks to deposit material on sidewalls of features. This may be referred to as sidewall passivation and uses conformal deposition methods in contrast to the vertical feature growth methods described herein. Conventional sidewall deposition methods can deposit a material on sidewalls using various reaction mechanisms. For example, a two-step ALD process can be used that first adsorbs a film onto a surface and then exposes the film to a reactant in a second step to convert the film to the desired deposition material. Another conventional sidewall deposition method is a one-step PE-CVD method using a reactant and a co-reactant (e.g., a gas mixture combining boron trichloride, nitrogen gas (N₂), and hydrogen gas (H₂)) at relatively high pressures (100 mT to 3000 mT).

In addition to the clear difference of depositing material on feature sidewalls rather than vertically on upper surfaces of features, the conventional sidewall deposition methods also differ from the proposed vertical feature growth methods in other ways. Notably, these conventional sidewall deposition mechanisms both require reactants with a low sticking coefficient (relatively few species “stick” to the surface in a given amount of time). This is to ensure that sufficient material is deposited on feature sidewalls deep into the spaces between the features. Another effect of the low sticking coefficient is that the rate of deposition is also slow. The ALD-based conventional sidewall deposition methods are even slower because the chamber must be purged between adsorption and conversion steps and the combination of the two steps only forms at most a few layers of deposited material.

Additionally, higher pressures during the conventional sidewall deposition methods ensure that a sufficient quantity of low-sticking coefficient reactants adsorb on sidewall surfaces (and that ion energies remain lower for the PE-CVD methods). This further facilitates sidewall deposition. Another difference between the conventional sidewall methods and the vertical feature growth methods herein described is the lack of applied bias power during both types of conventional sidewall deposition processes, which again relates to the goal of building up a passivating material on feature sidewalls rather than vertically.

Another type of conventional deposition method is a gap filling process that deposits a highly conformal thin film in high aspect ratio features (i.e., including bottom surfaces of recesses between features as well as feature sidewalls). The conformal thin film is used to deposit material at the bottom regions of the recesses so that voids are not formed when depositing a subsequent material to finish filling in the recess. The conventional gap filling method uses a conformal film deposition (CFD) process with two separate steps to deposit reactants (molecular ligands) followed by an activation step. The sharp corners of the conformally deposited film are then tapered using a subsequent etching step that etches faster at the top surfaces than at bottom surfaces of the gaps. More traditional deposition methods, such as CVD are then used to the fill in the gaps.

As with the conventional sidewall deposition methods, the conventional gap filling methods intentionally deposit materials conformally (i.e., on feature sidewalls and even bottom surfaces of recesses). Further, conventional deposition methods utilize only deposition processes while depositing the material (in order to encourage conformality of the deposited film), while the vertical feature growth methods include a fluorine-containing gas as an etchant to etch side protrusions during the deposition process. In the case of the conventional sidewall deposition methods, no etching of the deposited material is performed. For the conventional gap filling process, an isotropic etching step is performed after (i.e., separately from) the deposition process.

Therefore, whereas methods of depositing material such as oxide are known in the art, this invention proposes methods which avoid clogging by continually shaping the deposited material while it is being deposited.

Embodiment systems and methods of vertical feature growth using a fluorine-containing gas may overcome various shortcomings of conventional methods as well as provide other various advantages. For example, the fluorine-containing gas may be used to combat the clogging issue, by etching side protrusions of the deposited material (e.g., an oxide). In this way, a material may advantageously be deposited anisotropically (i.e., with preferentially vertical growth).

The feature growth methods may also have the advantage of being single-step processes. That is, the feature growth step includes both a deposition process and an etching process that occur simultaneously (i.e., concurrently) as opposed to cyclically. The embodiment methods may also have the advantage of being faster (e.g., have a higher deposition rate) than conventional deposition processes. For example, embodiment methods may be on the order of seconds while conventional deposition processes are on the order of minutes. In particular, the rate of feature growth of the methods described herein may be twenty or more times faster than conventional deposition methods, which may be a large throughput advantage.

Conventional deposition processes can require different tools to be used for etching and deposition processes. In contrast, the embodiment feature growth methods may have the advantage of being performed in situ in a single chamber (e.g., an etching chamber) which may also improve throughput and can allow in situ alternating between feature growth and etching of a target material without changing tools.

The feature growth methods described herein may also have the benefit of being highly flexible. For example, the relief pattern may be made of most any material, allowing growth of features in a variety of different applications. Advantageously, the feature growth methods may also be tunable, with various parameters being adjusted (e.g., relative gas flowrates, chemistry of the gas mixture, source power and/or bias power, etc.) to improve deposition rate and verticality without sacrificing feature profile.

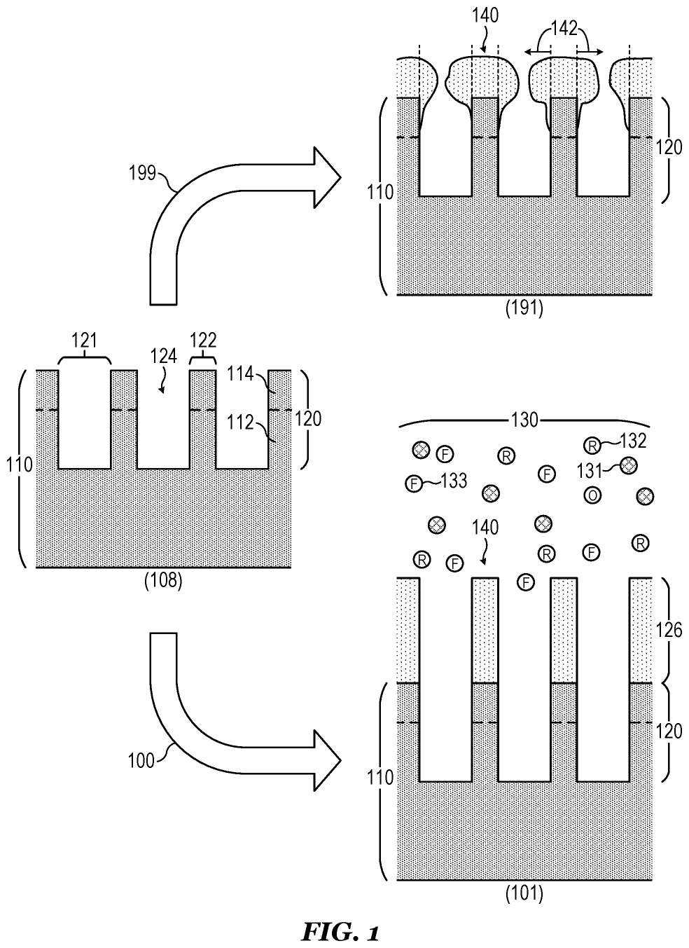

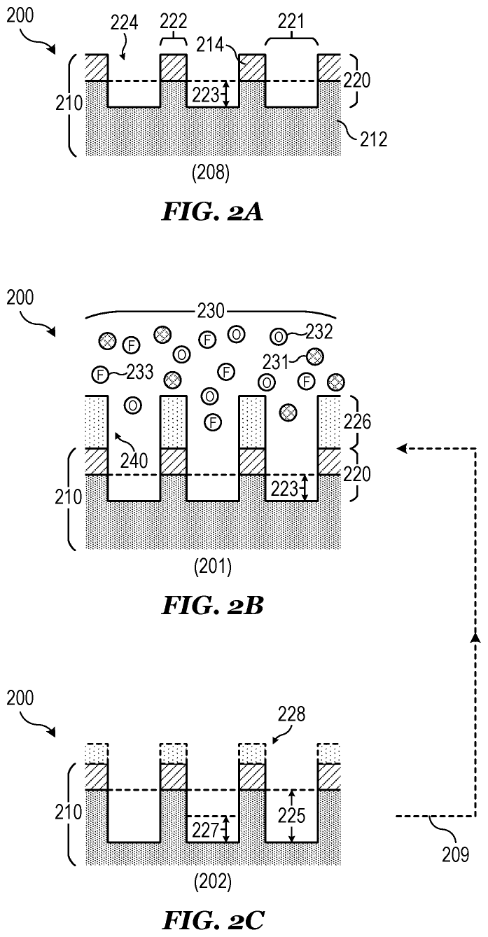

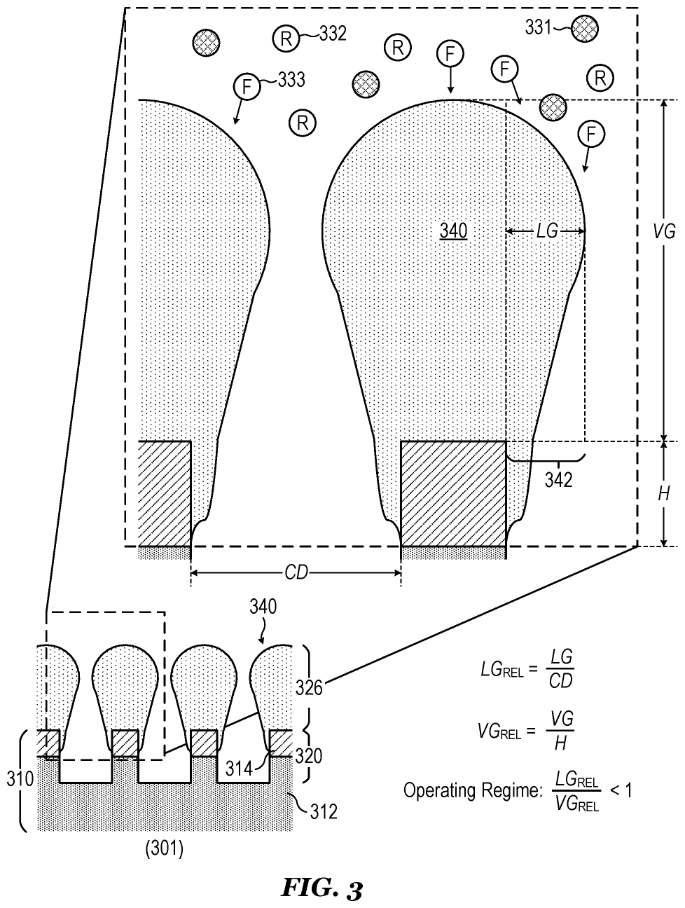

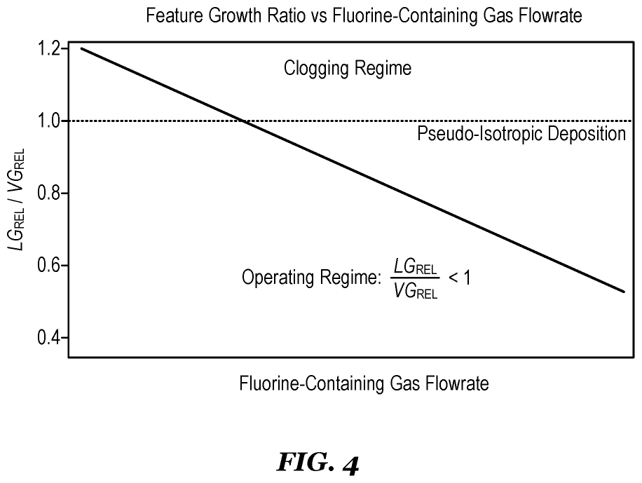

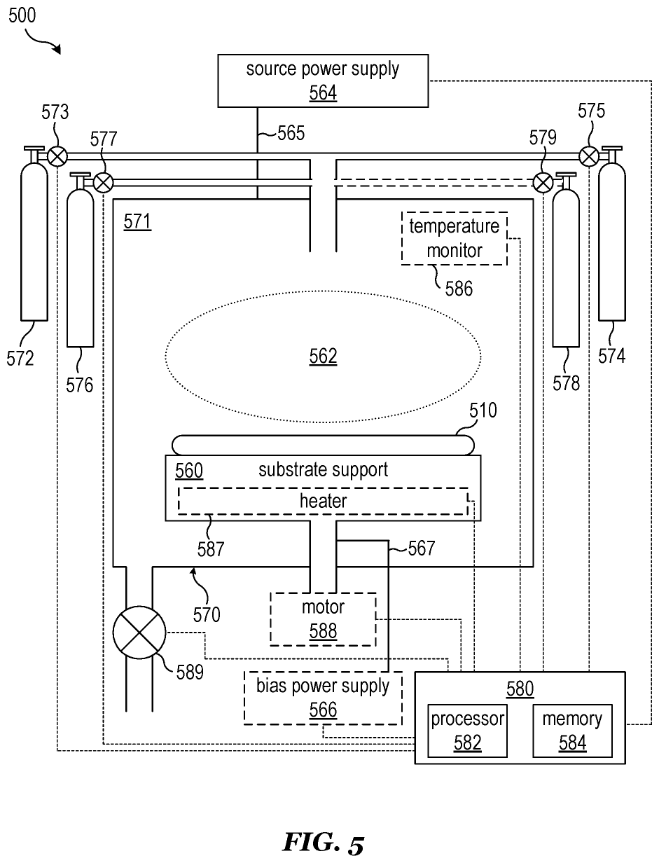

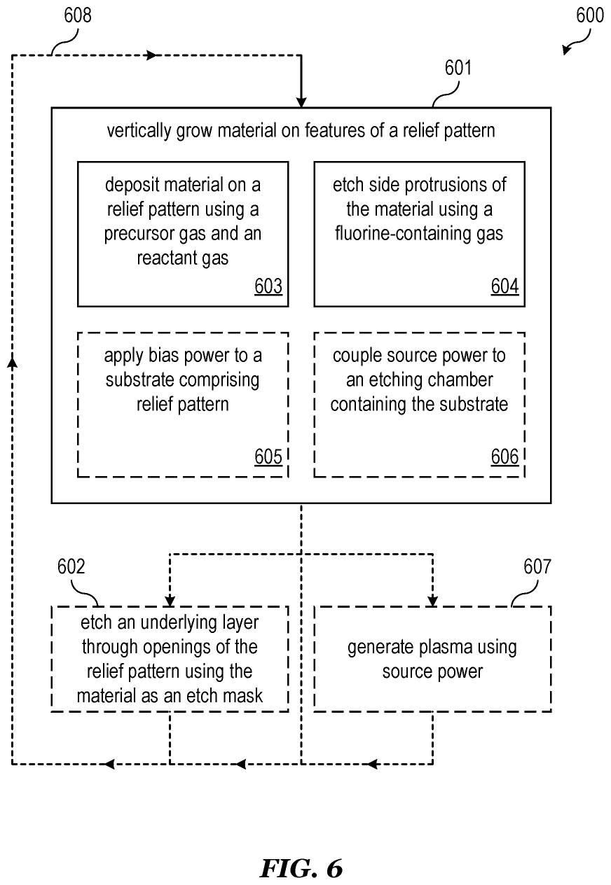

Embodiments provided below describe various systems and methods for vertically growing features on a relief pattern, and in particular embodiments, to systems and methods for vertically growing features on a relief pattern that use a fluorine-containing gas. The following description describes the embodiments. FIG. 1 is used to describe an example process for growing features of a relief pattern by concurrently depositing a material and etching side protrusions of the oxide. Another example process is described using FIG. 2. An example relief pattern that conceptually illustrates the etching of side protrusions of a deposited material is described using FIG. 3. FIG. 4 is used to describe a qualitative graph demonstrating an operating regime for feature growth. FIG. 5 is used to describe an example plasma processing system while an example feature growth method is described using FIG. 6.

FIG. 1 illustrates an example process for growing features of a relief pattern by concurrently depositing a material and etching side protrusions of the oxide in accordance with embodiments of the invention.

Referring to FIG. 1, a process 100 is performed on a substrate 110 that includes a relief pattern 120. For example, the relief pattern 120 has a non-planar topography with various features 122 separated by recesses 124 creating openings 121 between the features 122. The relief pattern 120 may include more than one material, such as when the relief pattern 120 includes a mask layer 114 formed over an underlying layer 112 (e.g., a target material for etching using the mask layer 114 as an etch mask). When the relief pattern 120 includes the mask layer 114 and the underlying layer 112, the recesses 124 may extend only through the mask layer 114 (such as when the mask has been developed/opened, but the underlying layer 112 has not been etched) or the recesses 124 may extend into the underlying layer 112 (as shown).

At the start of the process 100, the substrate 110 is in an initial state 108 where the features 122 of the relief pattern 120 have a particular height and profile. That is, regardless of the specific material makeup of the relief pattern 120, the initial state 108 represents a starting point with specific characteristics (e.g., the features 122 have some starting height, width, shape, etc.). If a conventional deposition process 199 (e.g., of an oxide) is performed on the substrate 110 in the initial state 108, a deposited material 140 is built up in a substantially isotropic manner on the features 122 so that side protrusions 142 (i.e., portions of the deposited material 140 that vertically overlap or overhang the recesses 124) extend into and/or over the openings 121 resulting in a narrowed relief pattern 191. As already mentioned, this narrowing may be detrimental to subsequent processes and would completely clog the openings if the conventional deposition process 199 is continued.

In contrast, when the process 100 is performed on the substrate 110 in its initial state 108, the deposited material 140 forms on the features 122 as feature growth 126 without substantial narrowing of the openings 121. Therefore, the process 100 results in preferentially vertical deposition of a material (such as an oxide), that substantially maintains the specific characteristics of the initial state 108 of the relief pattern 120. For this reason, the process 100 may be considered a feature growth process (or mask growth process when the relief pattern 120 includes a mask layer 114) that extends the features vertically with little or no lateral extension.

Specifically, the process 100 includes a feature growth step 101 that uses a gas mixture 130 (i.e., a processing gas) with a precursor gas 131, a reactant gas 132, and a fluorine-containing gas 133 (and that may include other gases). The gas mixture 130 simultaneously (i.e., concurrently) deposits the deposited material 140 using the precursor gas 131 and the reactant gas 132 and etches the side protrusions 142 with the fluorine-containing gas 133. As conceptually illustrated in FIG. 1, this may advantageously result in taller growths of the deposited material 140 as well as little or no lateral extension of the deposited material 140 over or into the openings 121.

The substrate 110 may be any suitable substrate, such as an insulating (e.g., a dielectric substrate), conducting (e.g., a metal substrate), or semiconducting substrate with one or more layers disposed thereon. One example category of possible substrates would be one of the many types of semiconductor wafer (e.g., silicon, silicon-on-insulator, germanium, gallium arsenide, etc.). In one embodiment, the substrate 110 comprises silicon. In another embodiment, substrate 110 is a ceramic substrate. Substrate 110 may also be a metallic substrate or include a metallic substrate. Of course, the substrate 110 may include various layers of any desirable material. For example, the substrate 110 may include additional layers (not shown) below the relief pattern 120 which may include functional structures (e.g., devices) or may merely be included for support.

Similarly, the underlying layer 112 may be any material. In some cases, the underlying layer 112 may be a target etch material, such as a semiconductor (e.g., silicon), a dielectric (silicon oxide, silicon nitride, etc.), and others. When a subsequent etch is performed after the feature growth step 101, it is a separate step. Therefore, the process 100 may have the advantage of imposing few (if any) restrictions on the material chosen for the underlying layer 112, which may instead depend on available etch chemistries and the specifics of a given application.

Similarly, the mask layer 114 may also be any suitable material. For example, the mask layer 114 may be a hardmask, such as a metal hardmask, a carbon-based hardmask (e.g., an amorphous carbon layer (ACL), diamond-like carbon, etc.), or other suitable materials for hardmasks in various applications, such as carbides, silicides, nitrides, and oxides. The mask layer 114 may also be a nitride mask, a photoresist (PR) mask, or an organic dielectric layer (ODL). In some embodiments, the mask layer 114 is a metal-oxide resist (MOR). For various reasons, MOR masks may be thin (e.g., have relatively short features) which may make the feature growth 126 using the process 100 advantageous for MOR masks.

Sometimes the relief pattern 120 may be a single material (e.g., without a distinction between a mask layer and an underlying layer). For example, a mask layer may have been present and was etched away (or otherwise removed) or the function of the relief pattern 120 is not to transfer or extend the pattern to an underlying layer. For these cases where the relief pattern 120 is a single material, the feature growth 126 may still be formed on the relief pattern using the feature growth step 101. In situations where a mask material was present and is no longer present, the feature growth 126 may even function as the entire etch mask in a subsequent etching process.

The feature growth step 101 may advantageously be tuned, such as by adjusting the absolute and relative quantities of the precursor gas 131, the reactant gas 132, and the fluorine-containing gas 133, as well as other constituent gases of the gas mixture 130. For example, the deposition rate may be tuned by adjusting the amounts of the precursor gas 131 and the reactant gas 132. Increasing the deposition rate may result in faster clogging, demonstrating a potential tradeoff between deposition rate and clogging. That is, when the deposited material 140 is deposited faster, it is deposited faster everywhere. This may be counteracted by tuning the etch rate of the side protrusions 142 (e.g., by increasing the absolute or relative amount of the fluorine-containing gas 133).

Other parameters may also be adjusted to tune the feature growth step 101. For example, bias power may be applied during the feature growth step 101. Similarly, source power may also be applied in some cases, such as when plasma is used in the feature growth step 101. Pressure may also play a role, since deposition rates may increase at higher pressure, but ion energy (e.g., energy of fluorine ions) may decrease and decreasing the etch rate of the side protrusions 142.

The deposited material 140 can be a wide range of materials, such as an oxide material or a nitride material that includes various elements such as silicon, aluminum, boron, titanium, and others. In one embodiment, the deposited material 140 is silicon oxide. In another embodiment, the deposited material 140 is aluminum oxide. In still another embodiment, the deposited material 140 is silicon nitride. In still yet another embodiment, the deposited material 140 is titanium nitride. Of course, many other materials may also be chosen for the deposited material 140.

The choice of the precursor gas 131 and the reactant gas 132 may depend on the choice of the deposited material 140 as well as properties of the various chemistries involved. In various embodiments, the precursor gas 131 is a halogen-containing precursor (e.g., including compounds bonded to halogen atoms). In some embodiments, the precursor gas 131 includes silicon. For example, the precursor gas 131 may be a silane compound such as silane (SiH₄), tetrachlorosilane (SiCl₄), tetrafluorosilane (SiF₄), and others. In another embodiment, the precursor gas 131 includes titanium. Some other examples include titanium tetrachloride (TiCl₄) and boron trichloride (BCl₃), but other possible compounds may be apparently to those of skill in the art in view of this disclosure.

The reactant gas 132 is selected so that a reaction between the precursor gas 131 and the reactant gas 132 is favorable. The reaction energy may be purely thermal energy or may be provided or supplemented using a plasma. In some embodiments, such as when depositing an oxide, the reactant gas 132 includes an oxygen-containing gas, such as dioxygen (O₂). In other embodiments, such as when depositing a nitride, the reactant gas 132 includes a nitrogen-containing gas, such as dinitrogen (N₂). Of course, other gases are also suitable for use as the reactant gas 132 and may depend on the specific details of a given application.

The fluorine-containing gas 133 may also be a wide range of compounds, as long as fluorine is included. For example, the fluorine-containing gas 133 may be a fluorocarbon compound, a hydrofluorocarbon compound, fluoronitrogen compound, and others (even potentially fluorine from a precursor gas such as SiF₄). Where the characterization applies, the fluorine-containing gas 133 may be a saturated or unsaturated compound. In one embodiment, the fluorine-containing gas 133 is tetrafluoromethane (CF₄). In another embodiment, the fluorine-containing gas 133 is trifluoromethane (CHF₃). In still another embodiment, the fluorine-containing gas 133 is nitrogen trifluoride (NF₃). However, many other compounds may also be used, such as sulfur hexafluoride (SF₆) as well as higher order compounds like hexafluoroethane (C₄F₆), and the like. In some cases, polymerizing fluorine-containing gas, such as higher order fluorocarbons, may increase polymer deposition, which may or may not be desirable. However, this may also be tuned, one example of which is by increasing the flowrate of the reactant gas (e.g., O₂).

The flowrates of the gases in the gas mixture 130 may take on a range or values. For example, the flowrate of the fluorine-containing gas 133 may be greater than about 25 sccm (standard cubic centimeters per minute) and is about 50 sccm in one embodiment. In some embodiments, the flowrate of the fluorine-containing gas 133 is greater than about 50 sccm, such as about 75 sccm, or higher.

The flowrate of the reactant gas 132 (e.g., O₂) is higher than the flowrate of the fluorine-containing gas 133 in some embodiments. In various embodiments, the flowrate of the reactant gas 132 is greater than about 100 sccm and is about 200 sccm in one embodiment. The flowrate of the reactant gas 132 may also be greater than 200 sccm, such as about 250 sccm and higher. In contrast, the flowrate of the precursor gas 131 may be lower than the flowrate of the fluorine-containing gas 133 (and the reactant gas 132). In various embodiments, the flowrate of the precursor gas 131 is greater than about 10 sccm (e.g., about 20 sccm), and may be greater than about 20 sccm, such as about 30 sccm, and higher.

Other gases may be included in the gas mixture 130 with various roles both related and unrelated to the feature growth step 101. For example, a carrier gas (e.g., an inert gas) may be included, such as argon, krypton, etc. The process 100 may be advantageously robust so as to allow a variety of other gases to be included when desired for various purposes, even potentially to include other modifications as part of the feature growth step 101 (a single-step process).

In keeping with the tunability of the process 100, other parameters may also have various values. For example, the process 100 may be performed at relatively low pressure (especially compared to conventional deposition methods), such as less than 250 mT. In one embodiment, the pressure is about 150 mT, but it may also be less than 150 mT, such as about 100 mT, and lower. When included, bias power applied to the substrate 110 may be greater than about 100 W, such as about 200 W, but may also be higher such as greater than 250 W, such as about 400 W, and higher. Similarly, applied source power may have any suitable value (e.g., in order to strike or maintain a plasma) and may be continuous wave during the feature growth step 101, or may also be pulsed. Moreover, when a subsequent etch step is included in the process 100, the source power and/or the bias power may be the same or different in the subsequent etch step compared to the feature growth step 101.

The additional height of the feature growth 126 over the features 122 may be advantageously large compared to the height of the relief pattern 120. For example, the feature growth 126 may be more than double the height of the relief pattern 120 (or at least the mask layer 114 when included). In one embodiment, the height of the feature growth 126 is more than about three times the height of the relief pattern 120. In another embodiment, the height of the feature growth 126 is more than about five times the height of the relief pattern 120. Of course, even larger relative height differences are possible, limited only by physical phenomena such as pattern collapse or increasing the aspect ratio of the relief pattern 120 (e.g., causing dimensioning returns since an etchant may no longer reach the bottoms of the recesses in a subsequent etch step).

The feature growth step 101 may have the advantage of being fast (e.g., relative to conventional deposition processes). In various embodiments, the duration of the feature growth step 101 is on the order of seconds, and is between about 5 s and about 30 s (such as about 10 s to about 15 s) in some embodiments. In contrast, conventional deposition processes are often on the order of minutes, such as 5 minutes for comparable deposition height (and with side protrusions potentially clogging recesses). In particular, the duration of the feature growth step 101 may be short because the deposition rate is fast, such as about 2 nm/s or faster.

In some cases, the profile of the vertical feature growth 126 may more closely match the underlying relief patter for hole patterns as opposed to line space patterns for the same set of parameters. For example, line space patterns have long edges that may contribute to increased lateral deposition. This may result in some non-zero clogging margin (e.g., <5-10% narrowing of openings) during the vertical feature growth method. However, how closely the feature growth matches the relief pattern may also be related to desired tuning (e.g., of the deposition rate as well as the eventual effect on etch profile). For example, in some cases, a 5% or 10% narrowing of the openings may be acceptable because the net deposition rate may be increased while a small amount of narrowing may have little or no effect on the desired outcome (e.g., a subsequent etch profile when using the feature growth as an etch mask). Of course, this may be another example of how the tunability of the process can be an advantage because the parameters of the vertical growth method may be tuned to produce the desired effects for a given application.

FIGS. 2A-2C illustrate another example process for growing features of a relief pattern by concurrently depositing oxide and etching side protrusions of the oxide, where the features are separated by openings as part of a mask layer and an underlying layer is etched through the openings using the oxide as an etch mask in accordance with embodiments of the invention. The process of FIG. 2 may be a specific implementation of other processes described herein such as the process of FIG. 1, for example. Similarly labeled elements may be as previously described.

Referring to FIG. 2, a process 200 that is performed on a substrate 210 that includes a relief pattern 220 begins with a feature growth step 201. It should be noted that here and in the following a convention has been adopted for brevity and clarity wherein elements adhering to the pattern [x10] where ‘x’ is the figure number may be related implementations of a feature growth step in various embodiments. For example, the feature growth step 201 may be similar to the feature growth step 101 except as otherwise stated. An analogous convention has also been adopted for other elements as made clear by the use of similar terms in conjunction with the aforementioned numbering system.

The relief pattern 220 has features 222 separated by recesses 224 creating openings 221 between the features 222. In this specific example, the relief pattern 220 includes a mask layer 214 overlying a underlying layer 212 (which here is a target material for a subsequent etch step) and the openings 221 extend through the mask layer 214 exposing the underlying layer 212. Although not required, by way of example, the recesses 224 are shown as extending into the underlying layer 212 a to a first recess depth 223 in the initial state 208.

During the feature growth step 201, the relief pattern 220 of the substrate 210 is exposed to a gas mixture 230 including a precursor gas 231, an oxygen-containing gas 232 (i.e., a specific implementation of the reactant gas 132), and a fluorine-containing gas 233. During the feature growth step 201, an oxide 240 is both deposited at upper surfaces of the features 222 and etched to remove side protrusions so that feature growth 226 that substantially matches the profile of the features 222 is formed. As shown, the underlying layer 212 is not etched during the feature growth step 201 and the first recess depth 223 remains substantially identical to the initial state 208.

However, after the feature growth step 201 (i.e., in a separate step after the feature growth 226 is formed), the process 200 further includes an underlying layer etch step 202 during which the underlying layer 212 is etched using at least the feature growth 226 as an etch mask 228 to a second recess depth 225 that results in an etch depth 227 (e.g., any existing recesses in the underlying layer 212 are deepened during the underlying layer etch step 202). The etching process may be any suitable process, but is a plasma etch in some embodiments. The etchant may be the same or different as the fluorine-containing gas 133 (although in some cases it is different by virtue of the underlying layer 212 being a different type of material than the feature growth 226). As shown, the etch mask 228 may be etched along with the underlying layer 212 (e.g., slower than the underlying layer 212, but not required). In some cases, the etch mask 228 may be etched away completely resulting in the original mask layer 214 functioning as the etch mask for the remainder of the underlying layer etch step 202.

For some etching applications, the combination of the feature growth step 201 and the underlying layer etch step 202 (and sometimes initial etching before the feature growth step 201) is insufficient to reach the desired etch depth within the underlying layer 212. In this case, the feature growth step 201 and the underlying layer etch step 202 may be repeated (e.g., alternated) as part of a cycle 209. This may advantageously be performed in situ in a single chamber (such as an etching chamber) which may provide the benefit of avoiding switching tools (decreased throughput) and additional tools (increased cost).

FIG. 3 illustrates an example relief pattern conceptually demonstrating etching of side protrusions of a deposited material resulting in vertical feature growth in accordance with embodiments of the invention. The relief pattern of FIG. 3 may be a specific implementation of other relief patterns described herein such as the relief pattern of FIG. 1, for example. Similarly labeled elements may be as previously described.

Referring to FIG. 3, a substrate 310 with a relief pattern 320 that includes a mask layer 314 and an underlying layer 312 is shown during a feature growth step 301. A conceptual structure of the deposited material 340 that includes side protrusions 342 is shown to demonstrate the effect of the etching using a fluorine-containing gas 333 that occurs simultaneously (i.e., concurrently) with depositing a deposited material 340 as feature growth 326 using a precursor gas 331 and a reactant gas 332.

Specifically, during the feature growth step 301, the deposited material is not only deposited vertically with some vertical growth (VG), but is also deposited laterally with some lateral growth (LG). Left unchecked, the deposited material 340 is deposited in a similar manner as conventional deposition processes narrowing the openings of the relief pattern (e.g., the narrowed relief pattern 191) and eventually clogging the pattern. However, the inclusion of a fluorine-containing gas 333 (and in some embodiments, applying bias power during the feature growth step 301) etches the side protrusions 342 so that the aggregate effect is to grow the feature growth 326 with a profile that is close to or the same as the profile of the relief pattern 320 (e.g., the mask layer 314, but also may simply be a relief pattern with no mask layer).

Intuitively, the profile of the feature growth 326 will approach the profile of the relief pattern 320 as VG increases relative to LG (i.e., VG>>LG). Since the feature growth step 301 includes deposition both in the vertical direction and in the horizontal direction, preferentially vertical growth will be achieved if VG>LG. In the absence of the fluorine-containing gas 333, the deposited material 340 will deposit substantially isotropically making VG approximately equal to LG. Although top regions of the feature growth 326 are etched by the fluorine-containing gas 333, the side protrusions 342 are etched more effectively (which may be due to the thinner material at the side protrusions 342, verticality of fluorine ions imparted by an applied bias power, or other factors) which reduces LG and can substantially eliminate the side protrusions 342 in some implementations (e.g., with tuning).

When LG is not substantially zero, both VG and LG will continue to increase over the duration of the feature growth step 301. Whether or not the absolute values of VG and LG for a given implementation of the feature growth step 301 are acceptable depends at least in part on the tolerance of subsequent processing steps to narrowing of the openings. At least one possible method of determining whether VG and LG are acceptable relates the vertical growth LG and the lateral growth LG to corresponding dimensions of the relief pattern 320; the critical dimension (CD) of the openings (i.e., the space CD of the features) and the mask height H (or in some cases the total recess height). Specifically, a relative lateral growth LG_{REL} can be defined as LG/CD while a relative vertical growth VG_{REL} can be defined as VG/H. Then, an operating regime can then be defined as the ratio of the relative lateral growth to the relative vertical growth, or in equation form: LG_{REL}/VG_{REL}<1. For example, the operating regime at least avoids clogging and may result in an acceptable profile of the feature growth 326.

FIG. 4 illustrates a qualitative graph of relative vertical growth versus lateral relative growth on features of a relief pattern demonstrating the operating regime for feature growth in accordance with embodiments of the invention. The qualitative graph of FIG. 4 may describe an operating regime for any of the methods and processes described herein, such as the process of FIG. 1 or the method of FIG. 6, as examples. Similarly labeled elements may be as previously described.

Referring to FIG. 4, a qualitative graph showing the feature growth ratio LG_{REL}/VG_{REL} as a function of the flowrate of the fluorine-containing gas. The operating regime is also plotted as a dotted line where the feature growth ratio is equal to one, indicating pseudo-isotropic growth. For example, the relative growth values depend on the underlying geometry so the feature growth ratio being equal to one does not necessarily indicate the vertical growth is equal to the lateral growth. Rather, the implication may be that amount of vertical growth and horizontal growth are equal when compared to the corresponding dimensions of the relief pattern.

As shown in the graph, the feature growth ratio may be adjusted by changing the flowrate of the fluorine-containing gas. In particular, increasing the flowrate may increase the etching of the side protrusions of the deposited material and lower the feature growth ratio (e.g., into the operating regime). Other parameters may also affect the feature growth ratio, and therefore may also be used to tune the profile of the deposited material (e.g., oxide) in a feature growth step. For example, increased pressure may increase the deposition rate making the side protrusions grow faster and causing the feature growth ratio to increase. Increased bias power may encourage faster etching of the side protrusions relative to etching of upper surfaces and the feature ratio may decrease. Of course, other parameters may also have an effect.

FIG. 5 illustrates an example plasma processing system that includes an etching chamber and a controller configured to both grow features of a relief pattern by concurrently depositing a material and etching side protrusions of the material and also to etch an underlying layer using the material as an etch mask in situ in the etching chamber in accordance with embodiments of the invention. The plasma processing system of FIG. 5 may be configured to perform any of the methods and processes described herein, such as the process of FIG. 1 or the method of FIG. 6, as examples. Similarly labeled elements may be as previously described.

Referring to FIG. 5, a plasma etching system 500 (e.g., a reactive-ion etching (RIE) etching system) includes a substrate support 560 disposed within an etching chamber 571, such as a plasma etching chamber, and configured to support a substrate 510. A precursor source 572 (e.g., a gas source or sources that include a precursor gas), a reactant source 574 (e.g., a gas source or sources including one or more reactant gases configured to react with the precursor gas to from a deposited material on features of a relief pattern), and a fluorine source 576 (e.g., a gas source or sources that include a fluorine-containing gas configured to etch the deposited material) are fluidically coupled to the etching chamber 571 through a precursor valve 573, a reactant valve 575, and a fluorine valve 577 respectively. Additional gas sources and valves may also be included in the plasma etching system 500. For example, an optional source 578 (e.g., a gas source or sources including additional gases, which may be any type of gas, such as carrier gases, additional reactants and precursors, stabilizers, catalysts and others) may be fluidically coupled to the etching chamber 571 through an optional valve 579. An exhaust valve 589 is also included to evacuate the etching chamber 571 during the processed performed therein, such as feature growth steps (e.g., including both deposition and etching processes as described in the foregoing), subsequent etching processes, and others.

The plasma etching system 500 is configured to generate a plasma 562 during at least etching processes, but also during a feature growth process. Specifically, a source power supply 564 is configured to couple source power 565 to the etching chamber 571 in order to generate the plasma 562. The etching chamber 571 may be any suitable etching chamber, such as a capacitively coupled plasma (CCP) etching chamber, an inductively coupled plasma (ICP) etching chamber, etc. A bias power supply 566 may also be included that is configured to supply bias power 567 to the substrate support 560 (and the substrate 510), such as to accelerate ions in the plasma 562 towards the substrate 510, for example. An optional temperature monitor 586 may also be included to monitor and/or aid in controlling the temperature of the substrate 510 and the environment in the etching chamber 571. An optional heater 587 may be included to elevate the temperature of the substrate 510 above the equilibrium temperature at the substrate 510 during the processes (although the feature growth processes may be performed at ambient temperatures). Alternatively, the optional heater 587 may be a cooler to decrease the temperature of the substrate 510 below equilibrium. An optional motor 588 may also be included to improve deposition uniformity.

A controller 580 is operatively coupled to source power supply 564 and the valves (the precursor valve 573, the reactant valve 575, the fluorine valve 577, the optional valve 579, etc.), and may be operatively coupled to any of the bias power supply 566 (when included), the optional temperature monitor 586, the optional heater 587, the optional motor 588, and the exhaust valve 589. The controller 580 includes a processor 582 and a memory 584 (i.e., a non-transitory computer-readable medium) that stores a program including instructions that, when executed by the processor 582, perform processes such as the feature grow processes and the subsequent etching processes described herein. For example, the memory 584 may have volatile memory (e.g., random access memory (RAM)) and non-volatile memory (e.g., flash memory). Alternatively, the program may be stored in physical memory at a remote location, such as in cloud storage. The processor 582 may be any suitable processor, such as the processor of a microcontroller, a general-purpose processor (such as a central processing unit (CPU), a microprocessor, a field-programmable gate array (FPGA), an application-specific integrated circuit (ASIC), and others.

FIG. 6 illustrates an example method of growing features of a relief pattern in accordance with embodiments of the invention. The method of FIG. 6 may be combined with other methods and performed using the systems and apparatuses as described herein. For example, the method of FIG. 6 may be combined with any of the embodiments of FIGS. 1-5. Although shown in a logical order, the arrangement and numbering of the steps of FIG. 6 are not intended to be limited. The method steps of FIG. 6 may be performed in any suitable order or concurrently with one another as may be apparent to a person of skill in the art.

Referring to FIG. 6, a method 600 of growing feature of a relief pattern includes a feature growth step 601 during which a material (e.g., oxide) is grown vertically on features of a relief pattern. The feature growth step 601 includes at least two concurrently performed sub-steps: a sub-step 603 where the material is deposited on the relief pattern using a precursor gas and a reactant gas and a sub-step 604 where side protrusions of the material are etched using a fluorine-containing gas. The feature growth step 601 may also include other optional sub-steps, also performed concurrently. For example, bias power may optionally be applied to a substrate comprising the relief pattern in an optional sub-step 605. Similarly, source power may be coupled to an etching chamber containing the substrate in an optional sub-step 606.

The deposited material may be used as an etch mask to etch and underlying layer through openings of the relief pattern in a subsequent etch step 602. When the subsequent etch step 602 is a plasma etch step, source power may be applied to generate plasma during an optional step 607 (e.g., using the same source power supply as may be used to apply source power during the feature growth step 601). When source power is utilized in both the feature growth step 601 and the subsequent etch step 602, the source power may have the same parameters or different parameters depending on the specific details of a given application. As before, the feature growth step 601 and the subsequent etch step may optionally be repeated (e.g., alternated) as part of a cycle 608.

Example embodiments of the invention are summarized here. Other embodiments can also be understood from the entirety of the specification as well as the claims filed herein.

Example 1. A method including performing the following concurrent steps: depositing a material on a relief pattern using a precursor gas and a reactant gas, the relief pattern including features separated by recesses; and etching side protrusions of the material vertically overlapping the recesses using a fluorine-containing gas.

Example 2. The method of example 1, where the concurrent steps further include: applying bias power to a substrate including the relief pattern.

Example 3. The method of one of examples 1 and 2, where the fluorine-containing gas includes nitrogen.

Example 4. The method of one of examples 1 to 3, where the reactant gas includes oxygen, and where the material is an oxide.

Example 5. The method of one of examples 1 to 4, further including: performing an etching step using the material as an etch mask to deepen the recesses.

Example 6. The method of example 5, where the concurrent steps and the etching step are alternated as part of a cycle.

Example 7. The method of one of examples 5 and 6, where the concurrent steps and the etching step are performed in situ in an etching chamber.

Example 8. The method of one of examples 1 to 7, where the relief pattern includes a metal-oxide resist.

Example 9. A method including: vertically growing oxide on features of a mask layer, the features being separated by openings exposing an underlying layer, where vertically growing the oxide includes concurrently depositing the oxide on the features using a precursor gas and an oxygen-containing gas, and etching side protrusions of the oxide vertically overlapping the openings using a fluorine-containing gas; and etching the underlying layer through the openings using the oxide as an etch mask.

Example 10. The method of example 9, where vertically growing the oxide on the features of the mask layer further includes applying bias power to a substrate including the mask layer and the underlying layer concurrently with depositing the oxide and etching the portions of the oxide.

Example 11. The method of one of examples 9 and 10, where the fluorine-containing gas includes a fluoronitrogen compound.

Example 12. The method of example 11, where the fluoronitrogen compound is nitrogen trifluoride.

Example 13. The method of one of examples 9 to 12 where vertically growing the oxide and etching the underlying layer are alternated as part of a cycle.

Example 14. The method of example one of examples 9 to 13, where vertically growing the oxide and etching the underlying layer are performed in situ in an etching chamber.

Example 15. The method of one of examples 9 to 14, where the mask layer includes a metal-oxide resist.

Example 16. A plasma etching system including: an etching chamber; a substrate support disposed in the etching chamber and configured to support a substrate including a mask layer disposed over an underlying layer, the mask layer including a relief pattern that includes features separated by openings exposing the underlying layer; at least one gas source fluidically coupled to the etching chamber and configured to supply a precursor gas, an oxygen-containing gas, and a fluorine-containing gas into the etching chamber; and a controller operatively coupled to the at least one gas source, the controller including a processor and a non-transitory computer-readable medium storing a program including instructions that, when executed by the processor, perform a method in situ in the etching chamber, the method including: vertically growing oxide on the features of the mask layer by concurrently depositing the oxide on the features using the precursor gas and the oxygen-containing gas, and etching side protrusions of the oxide vertically overlapping the openings using the fluorine-containing gas; and etching the underlying layer through the openings using the oxide as an etch mask.

Example 17. The plasma etching system of example 16, further including: a bias power supply coupled to the substrate support and operatively coupled to the controller, the bias power supply being configured to supply bias power, where vertically growing the oxide on the features of the mask layer further includes applying the bias power to the substrate concurrently with depositing the oxide and etching the portions of the oxide.

Example 18. The plasma etching system of one of examples 16 and 17, further including: a source power supply operatively coupled to the etching chamber and the controller, the source power supply being configured to supply source power, where etching the underlying layer includes generating plasma using the source power, and where vertically growing the oxide on the features of the mask layer further includes coupling the source power to the etching chamber concurrently with depositing the oxide and etching the portions of the oxide.

Example 19. The plasma etching system of one of examples 16 to 18, where vertically growing the oxide and etching the underlying layer are alternated as part of a cycle.

Example 20. The plasma etching system of one of examples 16 to 19, where the precursor gas includes tetrachlorosilane, the oxygen-containing gas includes dioxygen, and the fluorine-containing gas includes nitrogen trifluoride.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method comprising performing the following concurrent steps:
depositing a material on a relief pattern using a precursor gas and a reactant gas, the relief pattern comprising features separated by recesses; and
etching side protrusions of the material vertically overlapping the recesses using a fluorine-containing gas.

2. The method of claim 1, wherein the concurrent steps further comprise:
applying bias power to a substrate comprising the relief pattern.

3. The method of claim 1, wherein the fluorine-containing gas comprises nitrogen.

4. The method of claim 1, wherein the reactant gas comprises oxygen, and wherein the material is an oxide.

5. The method of claim 1, further comprising:
performing an etching step using the material as an etch mask to deepen the recesses.

6. The method of claim 5, wherein the concurrent steps and the etching step are alternated as part of a cycle.

7. The method of claim 5, wherein the concurrent steps and the etching step are performed in situ in an etching chamber.

8. The method of claim 1, wherein the relief pattern comprises a metal-oxide resist.

9. A method comprising:
vertically growing an oxide on features of a mask layer, the features being separated by openings exposing an underlying layer, wherein vertically growing the oxide comprises concurrently
depositing the oxide on the features using a precursor gas and an oxygen-containing gas, and
etching side protrusions of the oxide vertically overlapping the openings using a fluorine-containing gas; and
etching the underlying layer through the openings using the oxide as an etch mask.

10. The method of claim 9, wherein vertically growing the oxide on the features of the mask layer further comprises applying bias power to a substrate comprising the mask layer and the underlying layer concurrently with depositing the oxide and etching the portions of the oxide.

11. The method of claim 9, wherein the fluorine-containing gas comprises a fluoronitrogen compound.

12. The method of claim 11, wherein the fluoronitrogen compound is nitrogen trifluoride.

13. The method of claim 9, wherein vertically growing the oxide and etching the underlying layer are alternated as part of a cycle.

14. The method of claim 9, wherein vertically growing the oxide and etching the underlying layer are performed in situ in an etching chamber.

15. The method of claim 9, wherein the mask layer comprises a metal-oxide resist.

16. A plasma etching system comprising:
an etching chamber;
a substrate support disposed in the etching chamber and configured to support a substrate comprising a mask layer disposed over an underlying layer, the mask layer comprising a relief pattern that comprises features separated by openings exposing the underlying layer;
at least one gas source fluidically coupled to the etching chamber and configured to supply a precursor gas, an oxygen-containing gas, and a fluorine-containing gas into the etching chamber; and
a controller operatively coupled to the at least one gas source, the controller comprising a processor and a non-transitory computer-readable medium storing a program including instructions that, when executed by the processor, perform a method in situ in the etching chamber, the method comprising:
vertically growing oxide on the features of the mask layer by concurrently
depositing the oxide on the features using the precursor gas and the oxygen-containing gas, and
etching side protrusions of the oxide vertically overlapping the openings using the fluorine-containing gas; and
etching the underlying layer through the openings using the oxide as an etch mask.

17. The plasma etching system of claim 16, further comprising:
a bias power supply coupled to the substrate support and operatively coupled to the controller, the bias power supply being configured to supply bias power,
wherein vertically growing the oxide on the features of the mask layer further comprises applying the bias power to the substrate concurrently with depositing the oxide and etching the portions of the oxide.

18. The plasma etching system of claim 16, further comprising:
a source power supply operatively coupled to the etching chamber and the controller, the source power supply being configured to supply source power,
wherein etching the underlying layer comprises generating plasma using the source power, and
wherein vertically growing the oxide on the features of the mask layer further comprises coupling the source power to the etching chamber concurrently with depositing the oxide and etching the portions of the oxide.

19. The plasma etching system of claim 16, wherein vertically growing the oxide and etching the underlying layer are alternated as part of a cycle.

20. The plasma etching system of claim 16, wherein the precursor gas comprises tetrachlorosilane, the oxygen-containing gas comprises dioxygen, and the fluorine-containing gas comprises nitrogen trifluoride.
